(19) United States
(12) Patent Application Publication
(10) Pub. No.: US 2025/0292997 A1
(43) Pub. Date: Sep. 18, 2025

(54) PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 19/068,184

(22) Filed: Mar. 3, 2025

(30) Foreign Application Priority Data
Mar. 13, 2024 (JP) 2024-038950

(51) Int. Cl. H01J 37/32; H01F 27/24; H01F 27/30

(52) U.S. Cl. CPC H01J 37/32174; H01F 27/24; H01F 27/306; H01J 2237/24564

(57) ABSTRACT

A plasma processing apparatus includes: a chamber; a radio-frequency power supply configured to generate radio-frequency power and be capable of changing a frequency of the radio-frequency power; an introducer disposed to introduce electromagnetic waves into a plasma generation region within the chamber; a resonator having a power feeder, which is an entrance of the electromagnetic waves, and including a waveguide path configured to propagate the electromagnetic waves to the introducer; a coupler including an input portion to which the radio-frequency power is input, having a variable impedance, and connected between the radio-frequency power supply and the resonator; and a transmission line which is a distributed constant line extending from the input portion to the power feeder via the coupler and has a constant characteristic impedance.

### CROSS-REFERENCE TO RELATED APPLICATION

This application is based upon and claims the benefit of priority from Japanese Patent Application No. 2024-038950, filed on Mar. 13, 2024, the entire contents of which are incorporated herein by reference.

### TECHNICAL FIELD

Exemplary embodiments of the present disclosure relate to a plasma processing apparatus.

### BACKGROUND

A plasma processing apparatus has been used for plasma processing of a substrate. One type of plasma processing apparatus has a chamber, a radio-frequency power supply, a resonator, an introducer, and a matcher. The radio-frequency power supply is coupled to the resonator. Electromagnetic waves from the resonator are supplied into the chamber from the introducer. The matcher is connected between the radio-frequency power supply and the resonator. Such a plasma processing apparatus is disclosed in Patent Document 1 below.

### PRIOR ART DOCUMENTS

### Patent Documents

Patent Document 1: Japanese Patent Laid-open Publication No. 2020-92031

### SUMMARY

According to one embodiment of the present disclosure, there is provided a plasma processing apparatus including: a chamber; a radio-frequency power supply configured to generate radio-frequency power and be capable of changing a frequency of the radio-frequency power; an introducer disposed to introduce electromagnetic waves into a plasma generation region within the chamber; a resonator having a power feeder, which is an entrance of the electromagnetic waves, and including a waveguide path configured to propagate the electromagnetic waves to the introducer; a coupler including an input portion to which the radio-frequency power is input, having a variable impedance, and connected between the radio-frequency power supply and the resonator; and a transmission line which is a distributed constant line extending from the input portion to the power feeder via the coupler and has a constant characteristic impedance.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing a plasma processing apparatus according to one exemplary embodiment.

FIG. 2 is a diagram showing a lower portion of a resonator of the plasma processing apparatus according to one exemplary embodiment.

FIG. 3 is a cross-sectional view showing a coupler according to one exemplary embodiment.

FIG. 4 is a cross-sectional view taken along line IV-IV in FIG. 3.

FIG. 5 is an admittance chart related to the coupler according to one exemplary embodiment.

FIG. 6 is a cross-sectional view showing a coupler according to another exemplary embodiment.

FIG. 7 is a cross-sectional view taken along line VII-VII in FIG. 6.

FIG. 8 is a cross-sectional view showing a coupler according to another exemplary embodiment.

FIG. 9 is a cross-sectional view taken along line IX-IX in FIG. 8.

FIG. 10 is a cross-sectional view taken along line X-X in FIG. 8.

FIG. 11 is a diagram showing an inductor according to one embodiment employable in a coupler according to various exemplary embodiments.

FIG. 12 is a cross-sectional view showing a coupler according to another exemplary embodiment.

FIG. 13 is a cross-sectional view taken along line XIII-XIII in FIG. 12.

FIG. 14 is a table showing a relationship between a state (open or closed state) of a relay switch of each of a plurality of relays and inductance in a coupler according to another exemplary embodiment.

FIG. 15 is a diagram showing an example of the configuration for detecting a breakdown of a plurality of relays employable in a coupler according to various exemplary embodiments.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. Like reference numerals will be given to like or corresponding parts throughout the drawings.

Hereinafter, non-limiting exemplary embodiments are described with reference to the accompanying drawings. Throughout the drawings, the same or corresponding members or components are denoted by the same or corresponding reference numerals, and duplicated descriptions are omitted.

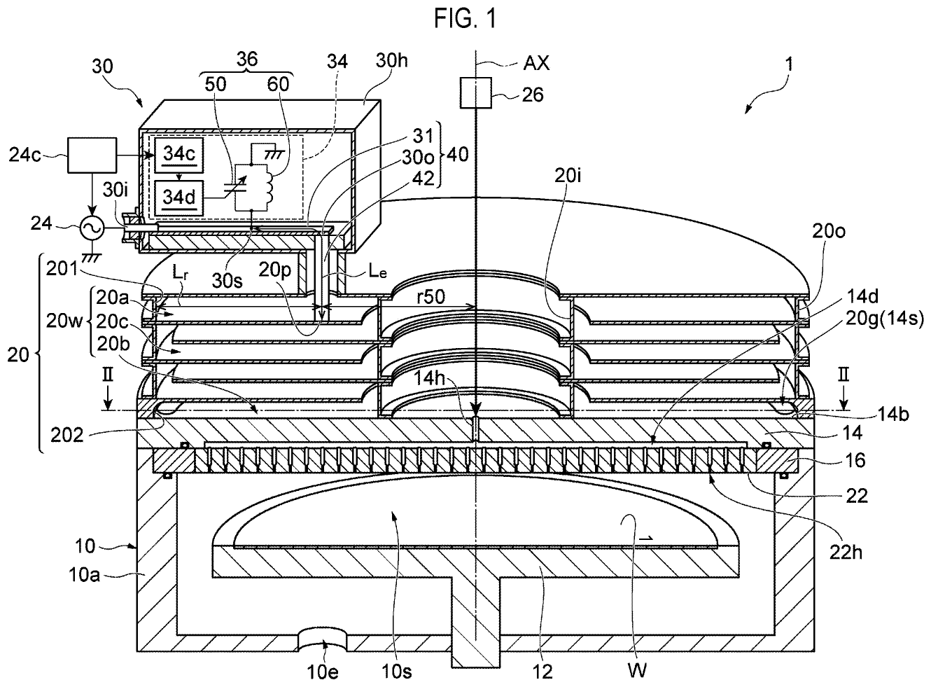

FIG. 1 is a diagram showing a plasma processing apparatus according to one exemplary embodiment. A plasma processing apparatus 1 shown in FIG. 1 includes a chamber 10, a substrate support 12, an introducer 16, a resonator 20, a radio-frequency power supply 24, and a coupler 30.

The chamber 10 includes a processing space 10s in the chamber 10. In the plasma processing apparatus 1, a substrate W is processed in the processing space 10s. The chamber 10 is made of a metal such as aluminum and is grounded. The chamber 10 has a sidewall 10a and is open at an upper end of the chamber 10. The chamber 10 and the sidewall 10a may have an approximately cylindrical shape. The processing space 10s is formed inside the sidewall 10a. A central axis of each of the chamber 10, the sidewall 10a, and the processing space 10s is an axis AX. The chamber 10 may have a corrosion-resistant film on surfaces of chamber 10. The corrosion-resistant film may be an yttrium oxide film, an yttrium oxide fluoride film, an yttrium fluoride film, or a ceramic film containing yttrium oxide, yttrium fluoride, or the like.

A bottom of the chamber 10 includes an exhaust port 10e. An exhaust device is connected to the exhaust port 10e. The exhaust device may include a vacuum pump, such as a dry pump and/or a turbomolecular pump, and an automatic pressure control valve.

The substrate support 12 is installed in the processing space 10s. The substrate support 12 is configured to approximately horizontally support the substrate W placed on an upper surface of the substrate support 12. The substrate support 12 has a substantially disc shape. A central axis of the substrate support 12 is the axis AX.

In one embodiment, the plasma processing apparatus 1 may further include an upper electrode 14. The upper electrode 14 is installed above the substrate support 12 via the processing space 10s. The upper electrode 14 is made of a conductor such as a metal (e.g., aluminum) and has an approximately disc shape. A central axis of the upper electrode 14 is the axis AX. The upper electrode 14 constitutes an excitation electrode together with a shower plate 22 described later.

The introducer 16 is installed to emit electromagnetic waves from the introducer 16 into a plasma generation region. In the plasma processing apparatus 1, the plasma generation region is a space within the processing space 10s and directly below the excitation electrode, i.e., directly below the shower plate 22. In the plasma processing apparatus 1, the electromagnetic waves emitted from the introducer 16 into the plasma generation region excite gas in the plasma generation region to generate plasma. The electromagnetic waves emitted from the introducer 16 into the plasma generation region may be radio-frequency waves such as VHF waves or UHF waves. The introducer 16 is made of a dielectric such as quartz, aluminum nitride, or aluminum oxide. In one embodiment, the introducer 16 is installed at a lateral end of the processing space 10s and extends in a circumferential direction around the axis AX. The introducer 16 may have an annular shape.

The resonator 20 includes a power feeder 20p and a waveguide path 20w. The power feeder 20p is an entrance of electromagnetic waves to the waveguide path 20w of the resonator 20. The electromagnetic waves are generated based on radio-frequency power generated by the radio-frequency power supply 24. The radio-frequency power supply 24 is configured to be capable of changing the frequency of the radio-frequency power. The electromagnetic waves are input to the power feeder 20p of the resonator 20 via the coupler 30 described later. The resonator 20 resonates the electromagnetic waves input to the power feeder 20p within the waveguide path 20w and propagates the electromagnetic waves to the introducer 16. The electromagnetic waves are introduced from the introducer 16 into the plasma generation region. In one embodiment, the resonator 20 may be installed above the chamber 10 and on the upper electrode 14.

In one embodiment, the plasma processing apparatus 1 may further include the shower plate 22. The shower plate 22 may be made of a metal such as aluminum. The introducer 16 extends to surround the shower plate 22. The introducer 16 and the shower plate 22 are disposed to close an opening at the upper end of the chamber 10. The shower plate 22 includes a plurality of gas holes 22h. The plurality of gas holes 22h extends in a thickness direction (vertical direction) of the shower plate 22 and penetrates the shower plate 22.

The shower plate 22 is installed below the upper electrode 14. The shower plate 22 extends above the plasma generation region. The shower plate 22 and the upper electrode 14 define a gas diffusion space 14d between the shower plate 22 and the upper electrode 14. A central axis of the gas diffusion space 14d may be the axis AX. The plurality of gas holes 22h of the shower plate 22 is connected to the gas diffusion space 14d. The upper electrode 14 includes an inlet 14h. The inlet 14h may extend along the axis AX. The inlet 14h is connected to the gas diffusion space 14d. A gas supply 26 is connected to the gas diffusion space 14d. Gas output from the gas supply 26 is supplied to the processing space 10s via the inlet 14h, the gas diffusion space 14d, and the plurality of gas holes 22h.

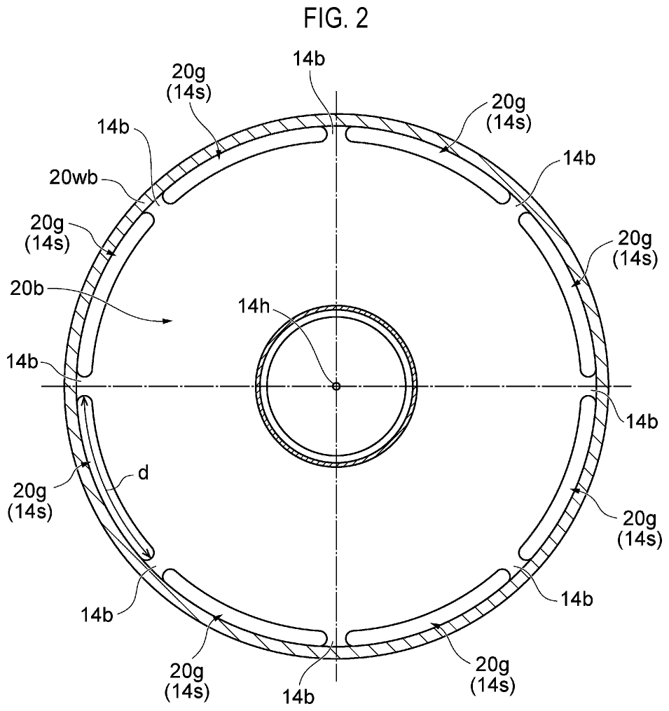

Hereinafter, reference will be made to FIG. 2 together with FIG. 1. FIG. 2 is a diagram showing a lower portion of the resonator of the plasma processing apparatus according to one exemplary embodiment. FIG. 2 is a cross-sectional view taken along line II-II in FIG. 1. The waveguide path 20w of the resonator 20 may provide a cavity surrounded by a wall. The wall of the waveguide path 20w is made of a material such as a metal. The wall of the waveguide path 20w may be made of an aluminum alloy, copper, nickel, stainless steel, or the like and may be coated with a low-resistance material such as silver, gold, rhodium, or the like.

The resonator 20 includes a first end 201 and a second end 202. The first end 201 and the second end 202 constitute one end and the other end of the waveguide path 20w of the resonator 20, respectively. The second end 202 is electromagnetically coupled to the introducer 16.

In one embodiment, the wall of the resonator 20 may include an inner peripheral portion 20i and an outer peripheral portion 200. The inner peripheral portion 20i extends around the axis AX, which is a central axis of the inner peripheral portion 20i, and has an approximately cylindrical shape. The outer peripheral portion 200 extends coaxially with the inner peripheral portion 20i around the axis AX. The outer peripheral portion 200 may have an approximately cylindrical shape.

The waveguide path 20w may have a layered structure that alternately folds between the inner peripheral portion 20i and the outer peripheral portion 200. The wall of the waveguide path 20w may include a plurality of walls that extend in a radial direction and a circumferential direction between adjacent layers of the layered structure and between the inner peripheral portion 20i and the outer peripheral portion 200. The plurality of walls may be annular plates. In addition, the waveguide path 20w may include an upper portion 20a constituting the uppermost layer of the layered structure and a lower portion 20b constituting the lowermost layer of the layered structure. The layered structure may include an intermediate portion 20c between the upper portion 20a and the lower portion 20b. In this embodiment, the upper portion 20a may include the first end 201, i.e., an upper stage, of the waveguide path 20w in the outer peripheral portion 200. In this case, the first end 201 of the waveguide path 20w extends in the circumferential direction around the axis AX. In addition, the lower portion 20b may include the second end 202, i.e., a lower stage, of the waveguide path 20w in the outer peripheral portion 200. In this case, the second end 202 of the waveguide path 20w extends in the circumferential direction around the axis AX.

The resonator 20 provides a plurality of gaps 20g in a vicinity of the second end 202 or along the second end 202. The plurality of gaps 20g is arranged in the circumferential direction around the axis AX. The electromagnetic waves resonating in the resonator 20 are electromagnetically propagated to the introducer 16 via the plurality of gaps 20g.

In one embodiment, the upper electrode 14 includes a plurality of slots 14s as the plurality of gaps 20g and includes a plurality of beams 14b. The plurality of slots 14s is disposed above the introducer 16. The plurality of slots 14s penetrates the upper electrode 14 in a thickness direction (vertical direction) of the upper electrode 14 and extends long in a circumferential direction. The plurality of slots 14s is spaced apart from each other and arranged in the circumferential direction around the axis AX. The plurality of slots 14s may be arranged at equal intervals. The plurality of beams 14b is arranged alternately with the plurality of slots 14s in the circumferential direction around the axis AX. The plurality of beams 14b connects an inner portion and an outer portion of the upper electrode 14 to each other.

In the plasma processing apparatus 1, resonance of electromagnetic waves occurs between the first end 201 and the second end 202. The electromagnetic waves resonating in the resonator 20 are supplied to the introducer 16 through the plurality of gaps 20g, i.e., the plurality of slots 14s. The electromagnetic waves supplied to the introducer 16 are emitted from the introducer 16 into the plasma generation region.

In addition, in the resonator 20, a distance d in a circumferential direction of each of the plurality of gaps 20g may satisfy Formula (F1) below:

$$0.05 {λ}_{g} < d < 0.3 {λ}_{g} \qquad ( F1 )$$

In Formula (F1), λ_{g} is a wavelength of the electromagnetic waves in the waveguide path 20w. When Formula (F1) is satisfied, the resonator 20 may supply a part of the electromagnetic waves propagating through the waveguide path 20w to the introducer 16 and may have an appropriately large reflection coefficient of the electromagnetic waves at the other end in the resonator 20.

A resonator length L₂₀ of the resonator 20 between the first end 201 and the second end 202 (a distance connecting the first end 201 and the second end 202 along the waveguide path 20w) may satisfy Formula (F2) below:

$$( n - 0.2 ) {λ}_{g} / 2 < {L}_{20} < n {λ}_{g} / 2 \qquad ( F2 )$$

In Formula (F2), λ_{g} is the wavelength of the electromagnetic waves in the waveguide path 20w, and n is an integer equal to or greater than 1. Reactance in the plurality of gaps 20g is inductive. Therefore, the resonator length L₂₀ may be set to a value slightly smaller than nλ_{g}/2 so as to satisfy Formula (F2).

The coupler 30 is connected between the radio-frequency power supply 24 and the resonator 20. The coupler 30 includes an input portion 30i, an output portion 300, and a supply line 31. The supply line 31 is extended to connect the input portion 30i and the output portion 300 to each other. The radio-frequency power supply 24 is connected to the input portion 30i. The output portion 300 is connected to the power feeder 20p via a supply line 42. That is, the supply line 42 connects the output portion 300 and the power feeder 20p to each other.

In the plasma processing apparatus 1, the supply line 31 constitutes a supply line 40 together with the supply line 42. The supply line 40 is a distributed constant line extending from the input portion 30i to the power feeder 20p via the coupler 30 and is a transmission line having a constant characteristic impedance. The constant characteristic impedance is, for example, 50Ω. The constant characteristic impedance may be 50Ω or less. In one embodiment, the supply line 31 in the coupler 30 may be configured as a microstrip line. In addition, the supply line 42 may be configured as a coaxial line.

The coupler 30 may further include a matching circuit 34. The matching circuit 34 is disposed within a grounded housing 30h (e.g., a metal housing). The matching circuit 34 includes a variable reactance portion 36 having a variable impedance. The variable reactance portion 36 is connected between a connection point 30s of the supply line 31 and a ground. The variable reactance portion 36 includes a capacitor 50 and/or an inductor 60. The matching circuit 34 further includes a driving circuit 34d and a control circuit 34c. The driving circuit 34d is configured as a circuit for changing the impedance of the variable reactance portion 36. The control circuit 34c is configured to control the driving circuit 34d. The control circuit 34c may be configured as a programmable processor such as a CPU or an MPU, a programmable logic device such as a field programmable gate array (FPGA), or a dedicated circuit such as an application specific integrated circuit (ASIC).

In the plasma processing apparatus 1, a voltage Vₘ₀ in the supply line 40 when there is no reflection from a load is (2×Z₀×P)^{1/2}. Here, Z₀ is a characteristic impedance of the supply line 40, and P is an incident power to the supply line 40. When the characteristic impedance Z₀ of the supply line 40 is 50Ω and the incident power P is 1 kW, the voltage Vₘ₀ is 316 V. Furthermore, even if total reflection occurs, a maximum voltage in the supply line 40 is twice the voltage Vₘ₀. Therefore, in the plasma processing apparatus 1, even if total reflection occurs, it is possible to suppress a maximum voltage in the coupler 30 caused by transmitted radio-frequency power in the coupler 30. In addition, in the plasma processing apparatus 1, the variable reactance portion 36 is connected to the supply line 31 included in the supply line 40. Therefore, as an element constituting the variable reactance portion 36, an element having a relatively small withstand voltage may be used. As a result, according to the plasma processing apparatus 1, the coupler 30 may be miniaturized. In addition, an element having a fast response speed may be used as an element in the matching circuit 34.

In one embodiment, the plasma processing apparatus 1 may further include a directional coupler and a power controller 24c. The directional coupler may be installed within the radio-frequency power supply 24 or between the radio-frequency power supply 24 and the input portion 30i. The power controller 24c may be configured as a programmable processor such as a CPU or MPU, a programmable logic device such as a field programmable gate array (FPGA), or a dedicated circuit such as an application specific integrated circuit (ASIC).

The directional coupler outputs a signal reflecting a power level of a reflected wave of the radio-frequency power to the power controller 24c. The power controller 24c controls the radio-frequency power supply 24 or the matching circuit 34 to reduce the power level of the reflected wave according to the signal from the directional coupler. The power controller 24c may control the radio-frequency power supply 24 to adjust the frequency of the radio-frequency power in order to reduce the power level of the reflected wave. Alternatively or additionally, the power controller 24c may communicate with the control circuit 34c to adjust the reactance of the variable reactance portion 36 in the matching circuit 34 in order to reduce the power level of the reflected wave.

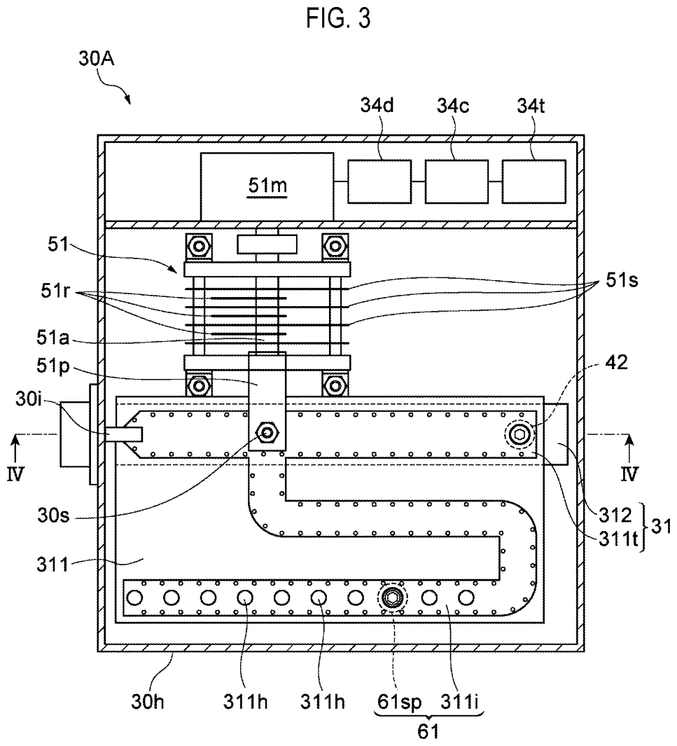

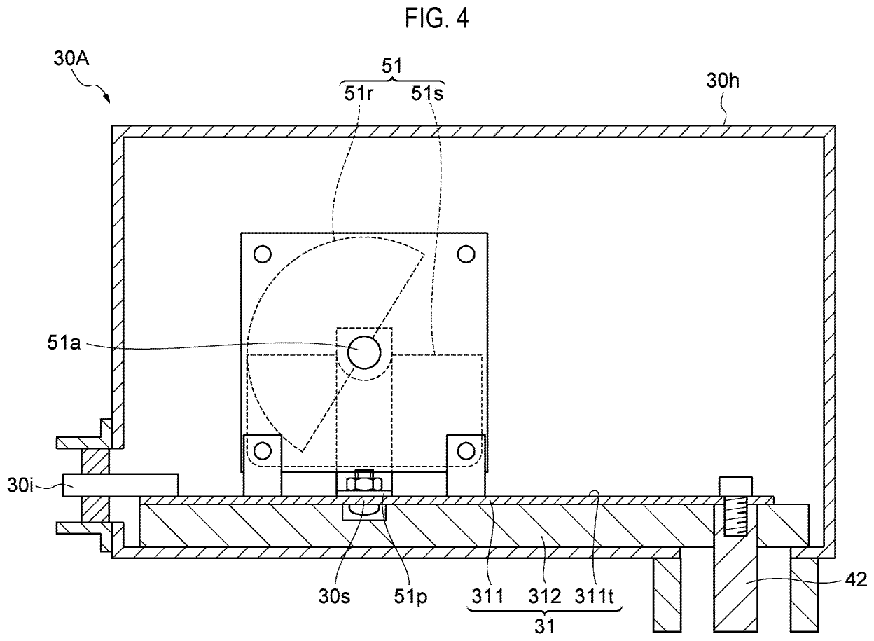

Hereinafter, reference will be made to FIGS. 3 and 4 together with FIG. 1. FIG. 3 is a cross-sectional view showing a coupler according to one exemplary embodiment. FIG. 4 is a cross-sectional view taken along line IV-IV in FIG. 3. FIG. 4 shows a structure in a longitudinal cross-section of the coupler according to one exemplary embodiment. A coupler 30A illustrated in FIGS. 3 and 4 may be used as the coupler 30 of the plasma processing apparatus 1.

The coupler 30A includes a printed circuit board 311 and a dielectric member 312. The printed circuit board 311 is provided within the housing 30h. The printed circuit board 311 has a transmission path pattern 311t. The transmission path pattern 311t extends from the input portion 30i to a connection point of the supply line 42 in a longitudinal direction thereof. The transmission path pattern 311t may be formed on both sides of the printed circuit board 311. The transmission path patterns 311t on both sides of the printed circuit board 311 have the same shape and are connected by a plurality of via conductors disposed along edges of the transmission path patterns 311t. The dielectric member 312 is installed between the transmission path pattern 311t and a bottom of the housing 30h. The dielectric member 312 is made of a material such as polytetrafluoroethylene.

The transmission path pattern 311t constitutes a microstrip line between the transmission path pattern 311t and the bottom of the housing 30h. This microstrip line has the above-described constant characteristic impedance. In addition, the dielectric member 312 may not be disposed in an area between the transmission path pattern 311t and the bottom of the housing 30h. The area between the transmission path pattern 311t and the bottom of the housing 30h may be filled with, for example, air.

In the plasma processing apparatus 1 including the coupler 30A, the power feeder 20p is disposed to have a distance r50 at which impedance of a load side from the power feeder 20p becomes 50Ω, under a desired plasma excitation condition (center condition) including the frequency of radio-frequency power, as a distance in a radial direction from the axis AX to the power feeder 20p. In this coupler 30A, the variable reactance portion 36 has a capacitor 51 as the capacitor 50 and an inductor 61 as the inductor 60.

The transmission path pattern 311t, i.e., a transmission line, includes a connection point 30s. The connection point 30s is located between the input portion 30i and the output portion 300. The capacitor 51 is connected to the connection point 30s via a metallic connection plate 51p. The capacitor 51 is a variable capacitor. The capacitor 51 includes a fixed electrode 51s, a rotating electrode 51r, and a rotating shaft 51a. The rotating shaft 51a extends in a horizontal direction and is rotatably supported around a central axis thereof. In addition, the rotating shaft 51a may extend in a direction other than the horizontal direction, for example, in a vertical direction.

The fixed electrode 51s is fixed so as not to move and is arranged approximately parallel to the rotating electrode 51r. The rotating electrode 51r has a fan-shaped or semicircular shape and is coupled to the rotating shaft 51a so as to be rotatable together with the rotating shaft 51a. In addition, the capacitor 51 may include a plurality of fixed electrodes 51s and a plurality of rotating electrodes 51r that are alternately arranged.

In this embodiment, the coupler 30A further includes a driving source 51m such as a motor and a communication circuit 34t. The driving source 51m is coupled to the rotating shaft 51a to rotate the rotating shaft 51a and the rotating electrode 51r. The driving source 51m rotates the rotating shaft 51a and the rotating electrode 51r according to an electrical signal from the driving circuit 34d. The driving circuit 34d is controlled by the control circuit 34c. The control circuit 34c is notified of a rotational angle position of the rotating electrode 51r for reducing the power level of the reflected wave by the power controller 24c via the communication circuit 34t. The control circuit 34c controls the driving source 51m via the driving circuit 34d so as to adjust the rotational angle position of the rotating electrode 51r to the notified rotational angle position. As a result, the capacitor 51 may change capacitance (electrostatic capacity) thereof.

In addition, one end of an inductor pattern 311i, which is a conductor pattern, is connected to the connection point 30s. The inductor pattern 311i extends from one end to the other end of the inductor pattern 311i. The inductor pattern 311i may be provided on both sides of the printed circuit board 311. The inductor patterns 311i on both sides of the printed circuit board 311 have the same shape and are connected by a plurality of via conductors disposed along edges of the inductor patterns 311i. By providing the inductor patterns 311i on both sides of the printed circuit board 311, the loss of radio-frequency power in the inductor 61 is suppressed.

The inductor pattern 311i is configured so that a length (electric field) from the one end of the inductor pattern 311i to a part short-circuited to a ground is changeable. In the embodiment of FIG. 3, a plurality of holes 311h penetrating the printed circuit board 311 in a thickness direction of the printed circuit board 311 is formed so as to be arranged between one end and the other end of the inductor pattern 311i. The inductor pattern 311i is short-circuited to the ground by screwing a screw inserted into a selected hole among the plurality of holes 311h into a screw hole of a short-circuit member 61sp (e.g., a metal pillar) that is held between the inductor pattern 311i and the bottom of the housing 30h. The inductor 61 may change the length of the inductor pattern 311i from one end of the inductor pattern 311i to a part short-circuited to the ground by changing a selected hole among the plurality of holes 311h. Thereby, the inductor 61 may change inductance thereof.

An inductance L of the inductor 61 is set to satisfy ωL=1/(ωCₕ). Here, ω is a plasma excitation angle frequency. In addition, Cₕ is a median value of a capacitance changeable range of the capacitor 51.

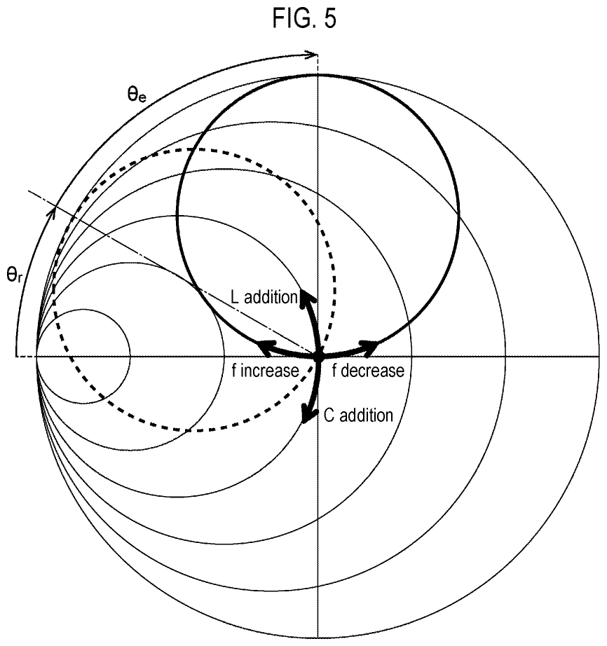

Hereinafter, reference will also made to FIG. 5. FIG. 5 is an admittance chart related to the coupler according to one exemplary embodiment. In FIG. 5, “f increase” or “f decrease” indicates the impedance of a load side of the connection point 30s and a change direction of a reflection coefficient corresponding thereto when the frequency of the radio-frequency power is increased or decreased. In addition, in FIG. 5, “L addition” or “C addition” indicates the impedance of the load side of the connection point 30s and the change direction of a reflection coefficient corresponding thereto when reactance of the variable reactance portion 36 is changed. Specifically, “L addition” indicates the impedance of the load side of the connection point 30s and a change in the reflection coefficient when the inductance of the variable reactance portion 36 is increased. In addition, “C addition” indicates the impedance of the load side of the connection point 30s and a change in the reflection coefficient when the capacitance of the variable reactance portion 36 is increased.

In the plasma processing apparatus 1, the position of the connection point 30s may be set to satisfy an orthogonal condition. That is, the position of the connection point 30s may be set so that a change in a reflection coefficient corresponding to the impedance of the load side of the connection point 30s when the reactance of the variable reactance portion 36 is changed (refer to an arrow on curves of equal conductance in FIG. 5) and a change in the reflection coefficient when the frequency of the radio-frequency power generated by the radio-frequency power supply 24 is changed (refer to an arrow on a thick solid line in FIG. 5) satisfy the orthogonal condition in a coordinate system with a real axis and an imaginary axis orthogonal to each other, as shown in FIG. 5.

When the orthogonal condition is satisfied, it is possible to greatly increase an impedance changeable range in the plasma processing apparatus 1. Further, the independence between a change in a load impedance caused by the change in the reactance in the variable reactance portion 36 and the change in the load impedance caused by the change in the frequency of the radio-frequency power generated by the radio-frequency power supply 24 is increased. Therefore, impedance matching is easily performed.

Hereinafter, a specific condition for satisfying the orthogonal condition will be described with reference to FIG. 5. If the orthogonal condition is satisfied, the impedance of the load side of the connection point 30s varies along a thick solid line in FIG. 5 when the frequency of the radio-frequency power generated by the radio-frequency power supply 24 is changed. In addition, the impedance of the load side viewed from the power feeder 20p varies along a circle indicated by a dashed line in FIG. 5 when the frequency of the radio-frequency power generated by the radio-frequency power supply 24 is changed. In FIG. 5, in order for an angle formed by a line extending through the center of a circle indicated by the thick solid line from a center point (a point indicating 50Ω) on a real axis with respect to the real axis to be 90 degrees in FIG. 5, it is necessary to set the position of the connection point 30s with respect to the power feeder 20p so that an angle de, which is the difference between an angle θᵣ, which is formed by a dash-single dotted line extending through the center of the circle represented by the dashed line from the center point (the point indicating 50Ω) on the real axis, and 90 degrees in FIG. 5, is achieved.

Here, the angle θᵣ is 4π×Lᵣ/λ_{gr}, and the angle θₑ is 4π×Lₑ/λ_{ge}. In addition, Lᵣ is a length in a radial direction between the power feeder 20p and an upper end (first end 201) of the resonator 20. λ_{gr} is a wavelength of electromagnetic waves in the waveguide path 20w of the resonator 20 between the power feeder 20p and the upper end (first end 201) of the resonator 20. Lₑ is a length between the power feeder 20p and the connection point 30s. λ_{ge} is a wavelength of the electromagnetic waves between the power feeder 20p and the connection point 30s. If the sum of the angle θᵣ and the angle θₑ is (2n+1) times 90 degrees, the orthogonality condition is satisfied. Therefore, the orthogonality condition is satisfied when Equation (1) below is satisfied. In addition, n is 0 or a positive integer.

$$\begin{matrix}[ Equation 1 ] & \\ \frac{{L}_{e}}{{λ}_{ge}} + \frac{{L}_{r}}{{λ}_{g r}} \tilde{=} \frac{2 n + 1}{8} & ( 1 )\end{matrix}$$

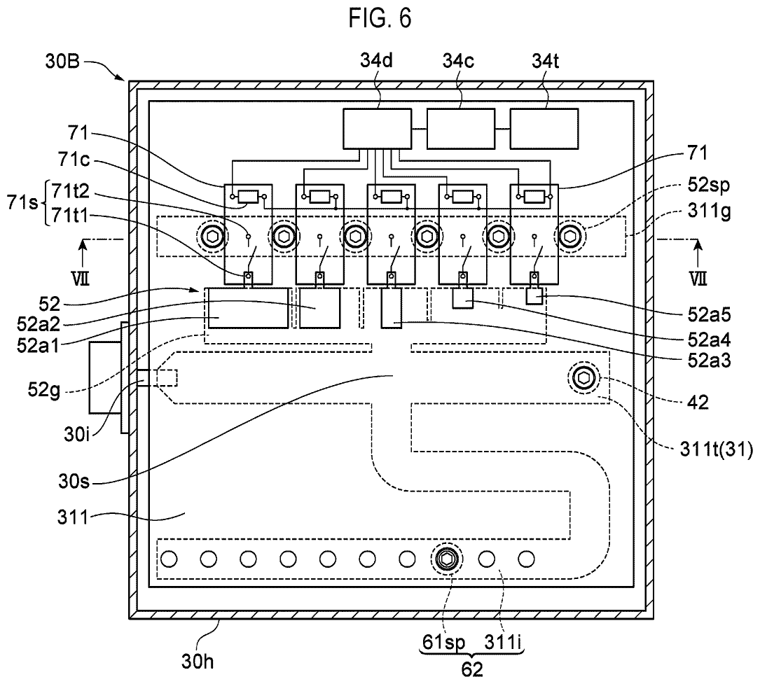

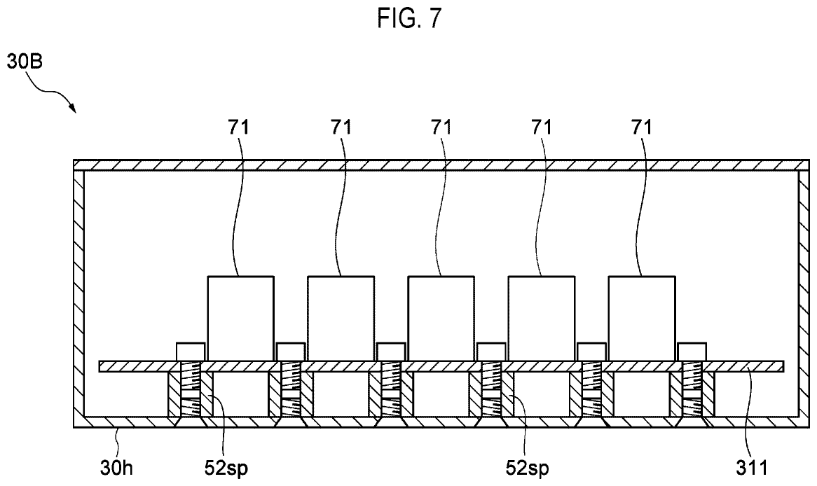

Hereinafter, the coupler according to another exemplary embodiment will be described with reference to FIGS. 6 and 7. FIG. 6 is a cross-sectional view showing a coupler according to another exemplary embodiment. FIG. 7 is a cross-sectional view taken along line VII-VII in FIG. 6. FIG. 7 shows a structure in a longitudinal cross-section of the coupler according to an exemplary embodiment. A coupler 30B shown in FIGS. 6 and 7 may be used as the coupler 30 of the plasma processing apparatus 1. Hereinafter, the coupler 30B will be described from the viewpoint of differences from the coupler 30A.

In the coupler 30B, the printed circuit board 311 may be made of a material having a small dielectric loss tangent. For example, the printed circuit board 311 may be made of a glass epoxy material having an inorganic material dispersed therein.

In the coupler 30B, the transmission path pattern 311t and the inductor pattern 311i are formed on a back surface of the printed circuit board 311. In the coupler 30B, the transmission path pattern 311t and the bottom of the housing 30h form the supply line 31, i.e., the above-described transmission line. In the coupler 30B, the inductor pattern 311i forms an inductor 62 of the variable reactance portion 36. The other configurations of the inductor 62 are the same as those of the inductor 61.

The coupler 30B includes a capacitor 52 as the capacitor 50 of the variable reactance portion 36. The capacitor 52 is formed of a plurality of capacitor elements. The number M of capacitor elements in the capacitor 52 may be any number of two or more.

The capacitor 52 includes a capacitor pattern 52g and capacitor patterns 52a1 to 52a5. The capacitor pattern 52g is formed on the back surface of the printed circuit board 311. The capacitor pattern 52g is connected to the connection point 30s. The capacitor patterns 52a1 to 52a5 are formed on an upper surface of the printed circuit board 311 so as to face the capacitor pattern 52g via the printed circuit board 311 (dielectric member).

The capacitor patterns 52a1 to 52a5 form a plurality of capacitor elements, respectively, together with the printed circuit board 311 and the capacitor pattern 52g. That is, the plurality of capacitor elements includes the capacitor patterns 52a1 to 52a5 as respective first electrodes thereof. The plurality of capacitor elements includes the capacitor pattern 52g as a common second electrode thereof. Additionally, the plurality of capacitor elements includes the printed circuit board 311 as a common dielectric member thereof.

In the capacitor 52, the capacitor pattern 52g may include a plurality of slits. To suppress interference between two adjacent capacitor elements, each of the plurality of slits extends between these capacitor elements.

The capacitor patterns 52a1 to 52a5 may have different areas so that the plurality of capacitor elements have different capacitances. The capacitance of each of the plurality of capacitor elements of the capacitor 52, i.e., an electrostatic capacity, may satisfy Cₘ=0.5×Cₘ₋₁. Here, Cₘ is the electrostatic capacitance of the m-th capacitor element among the 1st to M-th capacitor elements, which are the plurality of capacitor elements. The electrostatic capacities of the plurality of capacitor elements are, for example, 12.8 pF, 6.4 pF, 3.2 pF, 1.6 pF, and 0.8 pF, respectively.

In the coupler 30B, the matching circuit 34 further includes a plurality of relays 71. The plurality of relays 71 may be mounted on the upper surface of the printed circuit board 311. Each of the plurality of relays 71 includes a relay switch 71s and a relay coil 71c. The relay switch 71s includes a first connection point 71t1 and a second connection point 71t2 and may switch disconnection and connection between the first connection point 71t1 and the second connection point 71t2 depending on a state thereof (open or closed state). The first connection point 71t1 of the relay switch 71s of each of the plurality of relays 71 is connected to a corresponding capacitor pattern among the capacitor patterns 52a1 to 52a5. The second connection point 71t2 of the relay switch 71s of each of the plurality of relays 71 is connected to a ground pattern 311g provided on the back surface of the printed circuit board 311. The ground pattern 311g is connected to the bottom of the housing 30h, i.e., to a ground, via a plurality of short-circuit members 52sp (e.g., metal posts).

In the coupler 30B, the driving circuit 34d is configured to apply a direct current (DC) voltage signal for setting the state (open or closed state) of the relay switch 71s of each of the plurality of relays 71 to the relay coil 71c of each of the plurality of relays 71. The control circuit 34c may communicate with the power controller 24c via the communication circuit 34t. The control circuit 34c is notified of a capacitance setting value of the capacitor 52 for reducing the power level of the reflected wave by the power controller 24c via the communication circuit 34t. The control circuit 34c controls the driving circuit 34d to set the state of the relay switch 71s of each of the plurality of relays 71 in order to set the capacitance of the capacitor 52 to the notified setting value.

In the coupler 30B, the capacitance of the capacitor 52 may be adjusted by setting the state of the relay switch 71s of each of the plurality of relays 71. In one embodiment, the capacitance of the capacitor 52 may be changed in 32 binary steps.

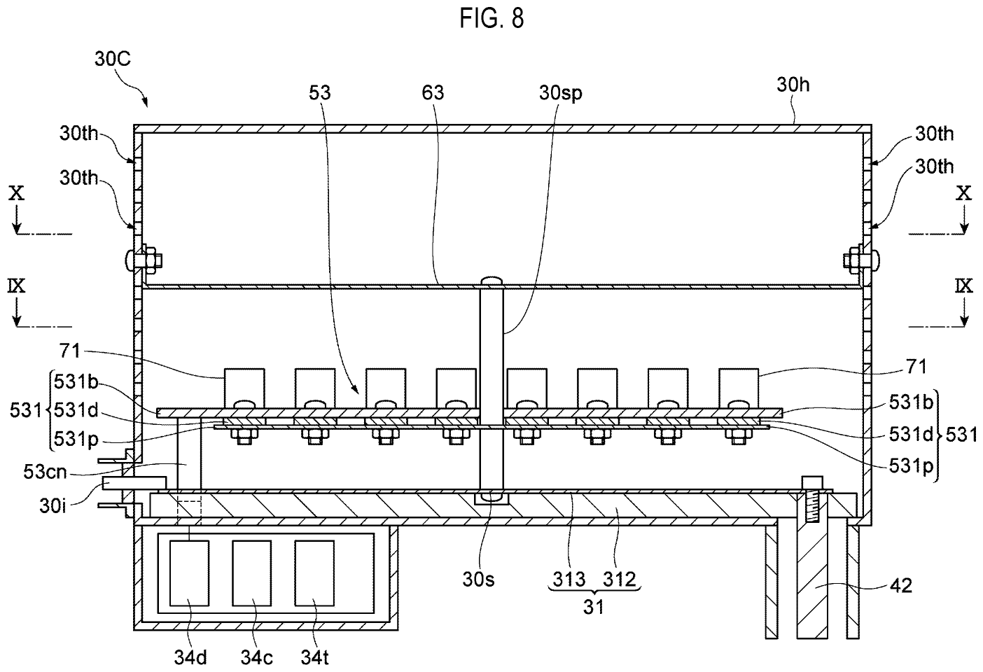

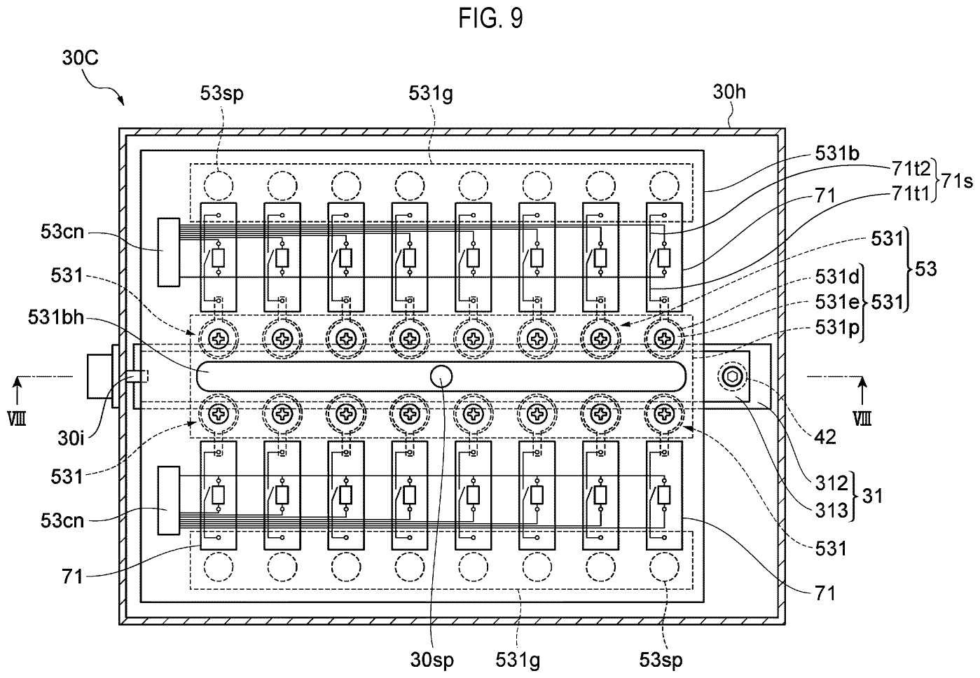

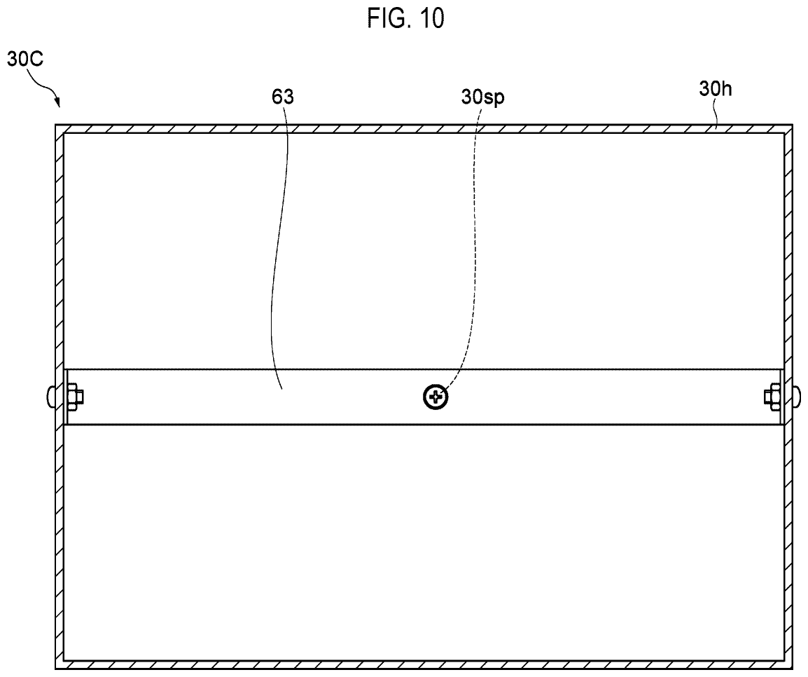

Hereinafter, the coupler according to another exemplary embodiment will be described with reference to FIGS. 8 to 10. FIG. 8 is a cross-sectional view showing a coupler according to still another exemplary embodiment. FIG. 9 is a cross-sectional view taken along line IX-IX in FIG. 8. FIG. 10 is a cross-sectional view taken along line X-X in FIG. 8. In addition, FIG. 8 shows the structure of the coupler according to still another exemplary embodiment in a longitudinal cross-section taken along line VIII-VIII in FIG. 9. A coupler 30C shown in FIGS. 8 to 10 may be used as the coupler 30 of the plasma processing apparatus 1. Hereinafter, the coupler 30C will be described from the viewpoint of differences from the coupler 30A.

The coupler 30C includes a transmission path plate 313 made of a metal such as copper. The transmission path plate 313 extends horizontally in a longitudinal direction thereof so as to connect the input portion 30i and the output portion 300 to each other. The dielectric member 312 is disposed between the transmission path plate 313 and the bottom of the housing 30h. The transmission path plate 313 constitutes the supply line 31 and constitutes a microstrip line together with the dielectric member 312 and the bottom of the housing 30h. The microstrip line has the above-described constant characteristic impedance.

The coupler 30C includes a capacitor 53 as the capacitor 50. The capacitor 53 has a plurality of capacitor elements 531. In order to provide the plurality of capacitor elements 531, the capacitor 53 includes a capacitor plate 531p, a plurality of dielectric members 531d, and a plurality of capacitor patterns 531e of a printed circuit board 531b.

The capacitor plate 531p is made of a metal such as copper and extends above the transmission path plate 313 in a horizontal direction. The transmission path plate 313 has a connection point 30s. The capacitor plate 531p is connected to the connection point 30s via a metal support 30sp (connection member). The metal support 30sp extends upward from the connection point 30s.

The printed circuit board 531b extends above the capacitor plate 531p in a horizontal direction. The plurality of capacitor patterns 531e is formed on a back surface (bottom surface) of the printed circuit board 531b so as to face the capacitor plate 531p. Each of the plurality of capacitor patterns 531e may have an approximately circular shape. The plurality of capacitor patterns 531e may be arranged in a longitudinal direction of the capacitor plate 531p. In the illustrated example, the plurality of capacitor patterns 531e is arranged to form two rows extending in a direction parallel to the longitudinal direction of the capacitor plate 531p. The printed circuit board 531b may include a slit 531bh penetrating the printed circuit board 531b in a thickness direction of the printed circuit board 531b. The slit 531bh may be formed between the two rows of the plurality of capacitor patterns 531e. A parasitic capacitance of the printed circuit board 531b may be reduced by the slit 531bh.

Each of the plurality of dielectric members 531d is held by a screw between a corresponding capacitor pattern among the plurality of capacitor patterns 531e and the capacitor plate 531p. The plurality of dielectric members 531d may be made of polytetrafluoroethylene or the like and may have a ring shape. An edge of each of the plurality of capacitor patterns 531e may have a size slightly smaller than the size of each of the plurality of dielectric members 531d so as to be positioned inside an edge of a corresponding dielectric member among the plurality of dielectric members 531d. As a result, creeping discharge may be suppressed.

In the capacitor 53, each of the plurality of capacitor elements 531 includes a corresponding capacitor pattern among the plurality of capacitor patterns 531e and a corresponding dielectric member among the plurality of dielectric members 531d. In addition, the plurality of capacitor elements 531 shares the capacitor plate 531p. The plurality of capacitor patterns 531e may have the same area as each other. In this case, the plurality of capacitor elements 531 has the same capacitance as each other. In another embodiment, the plurality of capacitor elements 531 may have different capacitances.

The matching circuit 34 of the coupler 30C further includes a plurality of relays 71. In the coupler 30C, the plurality of relays 71 has the same configuration as the plurality of relays 71 in the coupler 30B. In the coupler 30C, the plurality of relays 71 is provided on the printed circuit board 531b. In the coupler 30C, a first connection point 71t1 of a relay switch 71s of each of the plurality of relays 71 is connected to a corresponding capacitor pattern among the plurality of capacitor patterns 531e. In the coupler 30C, a second connection point 71t2 of a relay switch 71s of each of the plurality of relays 71 is connected to a ground pattern 531g provided on a back surface of the printed circuit board 531b. The ground pattern 531g is connected to the bottom of the housing 30h, i.e., the ground, via a plurality of metal posts 53sp.

In addition, in the coupler 30C, the driving circuit 34d is connected to the relay coil 71c of each of the plurality of relays 71 via a connector 53cn. The driving circuit 34d is configured to apply a DC voltage signal for setting the state (open or closed state) of the relay switch 71s of each of the plurality of relays 71 to the relay coil 71c of each of the plurality of relays 71. The control circuit 34c may communicate with the power controller 24c via the communication circuit 34t. The control circuit 34c is notified of a capacitance setting value of the capacitor 53 for reducing the power level of the reflected wave by the power controller 24c via the communication circuit 34t. The control circuit 34c controls the driving circuit 34d to set the state of the relay switch 71s of each of the plurality of relays 71 in order to set the capacitance of the capacitor 53 to the notified setting value. In the coupler 30C, the capacitance of the capacitor 53 may be adjusted by adjusting the state (open or closed state) of the relay switch 71s of each of the plurality of relays 71.

In addition, in the coupler 30C, the matching circuit 34 includes an inductor 63 as the inductor 60. The inductor 63 is composed of an inductor plate, which is a conductor plate made of a metal such as copper. The inductor plate extends above the printed circuit board 531b in a horizontal direction. The inductor plate is connected to the connection point 30s via the metal support 30sp.

A plurality of pairs of holes 30th is formed in a pair of side walls of the housing 30h. The plurality of pairs of holes 30th is arranged in a vertical direction. Both ends of the inductor plate are fixed to a pair of side walls of the housing 30h using a pair of screws and a pair of nuts that are inserted into a pair of holes 30th selected from among the plurality of pairs of holes 30th. In the coupler 30C, it is possible to change an electric field between the inductor plate and the connection point 30s by changing a pair of holes 30th selected from among the plurality of pairs of holes 30th. As a result, the inductance of the inductor 63 may be changed.

In addition, in the coupler 30C, the plurality of capacitor elements 531 is arranged in one or more rows. However, the plurality of capacitor elements 531 may be arranged in a circumferential direction around an axis extending in a vertical direction from the connection point 30s. The plurality of capacitor elements 531 may be arranged at equal intervals. In addition, the plurality of relays 71 may be arranged in a circumferential direction on an outer side of the plurality of capacitor elements 531 in a radial direction.

In another embodiment, the power feeder 20p may be provided at an outer position with respect to a position in a radial direction at which the impedance of the load side from the power feeder 20p becomes 50Ω. That is, a distance in a radial direction from the axis AX to the power feeder 20p may be longer than the distance r50 described above. In this case, in the variable reactance portion 36 of the plasma processing apparatus, only the capacitor 50 may have a variable reactance, and the variable reactance portion 36 may have the inductor 60. As the capacitor 50, any one of various capacitors disclosed herein, such as capacitors 51 to 53, may be employed.

In still another embodiment, the power feeder 20p may be provided at an inner position with respect to the position in the radial direction at which the impedance of the load side from the power feeder 20p becomes 50Ω. That is, a distance in the radial direction from the axis AX to the power feeder 20p may be shorter than the distance r50 described above. In this case, in the coupler of the plasma processing apparatus, only the inductor 60 may have variable reactance.

Hereinafter, various exemplary embodiments of the inductor 60 having a variable inductance and exemplary embodiments of a coupler having such an inductor will be described.

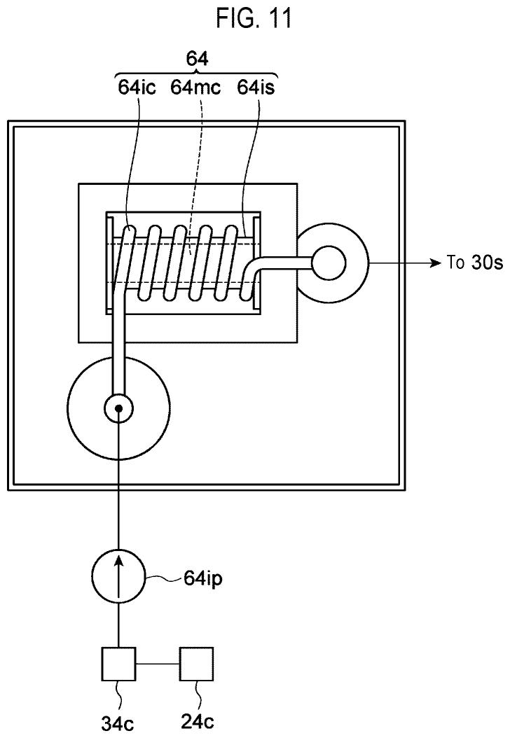

Reference is made to FIG. 11. FIG. 11 is a diagram showing an inductor according to one embodiment employable in a coupler according to various exemplary embodiments. An inductor 64 shown in FIG. 11 is employable as an inductor of a variable reactance portion of the coupler according to various exemplary embodiments. The inductor 64 includes a coil 64ic, a core 64mc (magnetic core), and an insulating cover 64is. The coil 64ic is made of a metal such as copper and is wound around the core 64mc. The insulating cover 64is is made of an epoxy resin or the like and is disposed between the coil 64ic and the core 64mc so as to cover the core 64mc.

One end of the coil 64ic is connected to the connection point 30s. The other end of the coil 64ic may be connected to a ground via a capacitor. A current source 64ip is connected to the other end of the coil 64ic. In this case, the control circuit 34c controls the current source 64ip to adjust DC current supplied to the coil 64ic. When the current is supplied to the coil 64ic, the core 64mc is excited, and the permeability of the core 64mc changes due to the nonlinearity of a B-H curve of the core 64mc. Therefore, the inductance of the inductor 64 may be controlled by controlling the DC current supplied to the coil 64ic from the current source 64ip. The control circuit 34c is notified of an inductance setting value that is set to reduce the power level of the reflected wave by the power controller 24c. The control circuit 34c adjusts the DC current supplied to the coil 64ic from the current source 64ip according to the notified setting value.

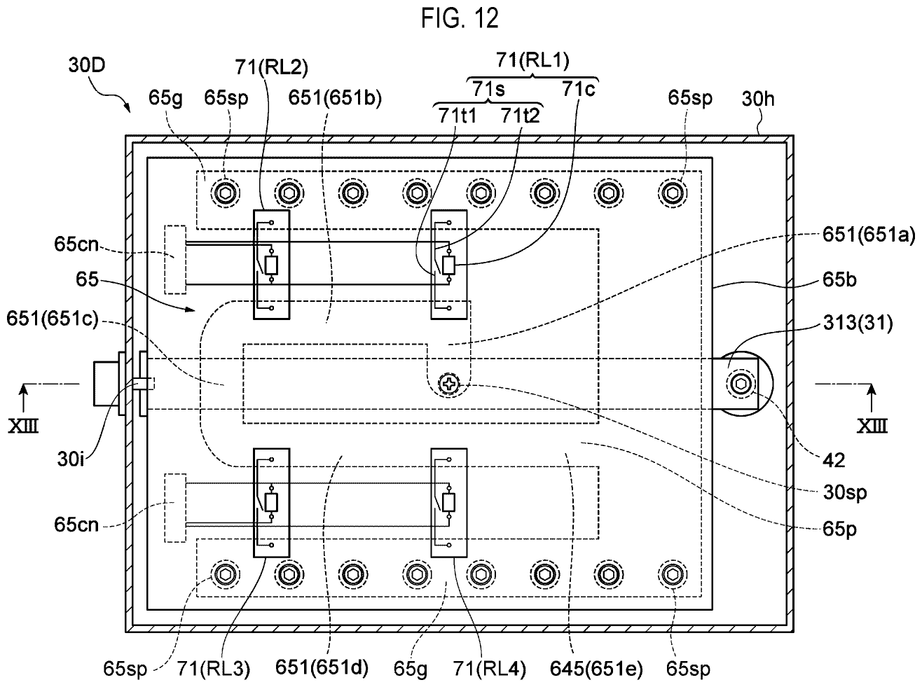

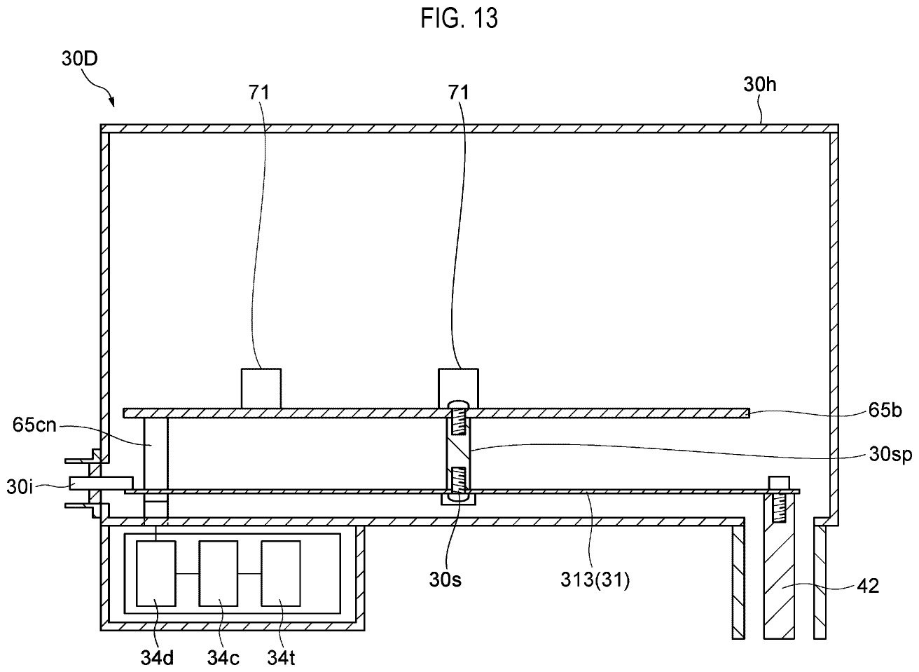

Hereinafter, reference will be made to FIG. 12 and FIG. 13. FIG. 12 is a cross-sectional view showing a coupler according to another exemplary embodiment. FIG. 13 is a cross-sectional view taken along line XIII-XIII in FIG. 12. FIG. 13 shows a structure in a longitudinal cross-section of the coupler according to another exemplary embodiment. Hereinafter, a coupler 30D shown in FIG. 12 and FIG. 13 will be described from the viewpoint of differences from the coupler 30A.

The coupler 30D includes a transmission path plate 313 made of a metal such as copper. The transmission path plate 313 extends horizontally in a longitudinal direction thereof so as to connect the input portion 30i and the output portion 300 to each other. The transmission path plate 313 constitutes the supply line 31 together with the bottom of the housing 30h and constitutes a microstrip line. The microstrip line has the above-described constant characteristic impedance.

In the coupler 30D, the matching circuit 34 includes an inductor 65 as the inductor 60. The inductor 65 includes an inductor pattern 65p. The inductor pattern 65p is formed on a back surface of a printed circuit board 65b. The printed circuit board 65b extends above the transmission path plate 313 in a horizontal direction. One end of the inductor pattern 65p may be disposed at the center of the inductor pattern 65p or the center of the printed circuit board 65b. One end of the inductor pattern 65p is connected to the connection point 30s of the transmission path plate 313 via the metal support 30sp (connecting member). The other end of the inductor pattern 65p is connected to a ground pattern 65g formed on the back surface of the printed circuit board 65b. The ground pattern 65g is connected to the bottom of the housing 30h via a plurality of metal supports 65sp.

In the coupler 30D, the matching circuit 34 further includes the plurality of relays 71. The plurality of relays 71 is provided on the printed circuit board 65b. Each of the plurality of relays 71 in the coupler 30D has the same configuration as the relay 71 of the coupler 30B described above. A first connection point 71t1 of each of the plurality of relays 71 is connected to a different position of the inductor pattern 65p between one end and the other end of the inductor pattern 65p. A second connection point 71t2 of each of the plurality of relays 71 is connected to the ground pattern 65g. The plurality of relays 71 divides the plurality of inductor patterns 65p into a plurality of inductor elements 651. In the illustrated example, the plurality of relays 71 includes four relays RL1 to RL4. In this example, the inductor pattern 65p is divided into five inductor elements 651a to 651e between one end and the other end thereof.

In the matching circuit 34 of the coupler 30D, the driving circuit 34d is connected to the relay coil 71c of each of the plurality of relays 71 via the connector 65cn. The driving circuit 34d is configured to apply a DC voltage signal for setting the state (open or closed state) of the relay switch 71s of each of the plurality of relays 71 to the relay coil 71c of each of the plurality of relays 71. The control circuit 34c may communicate with the power controller 24c via the communication circuit 34t. The control circuit 34c is notified of an inductance setting value of the inductor 65 for reducing the power level of the reflected wave by the power controller 24c via the communication circuit 34t. The control circuit 34c controls the driving circuit 34d to set the state of the relay switch 71s of each of the plurality of relays 71 in order to set the inductance of the inductor 65 to the notified setting value. In the coupler 30D, the inductance of the inductor 65 may be adjusted by setting the state of the relay switch 71s of each of the plurality of relays 71.

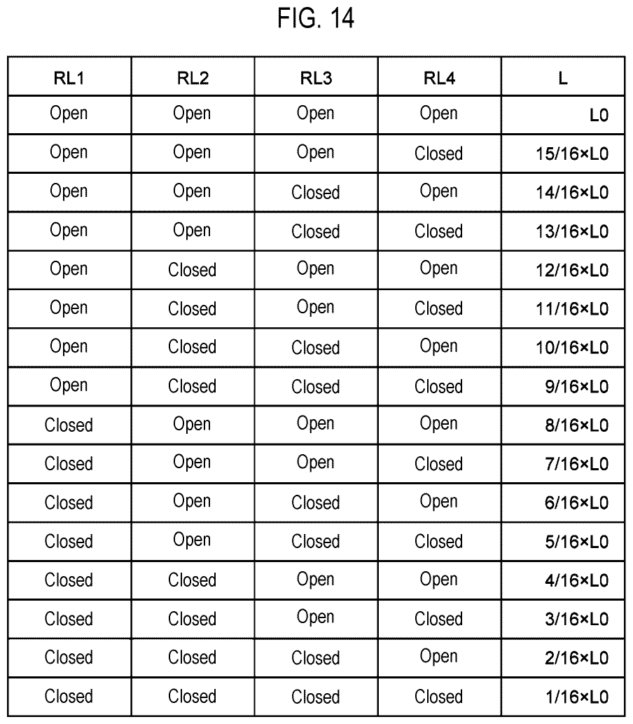

FIG. 14 is a table showing the relationship between the state (open or closed state) of a relay switch of each of a plurality of relays and inductance in a coupler according to another exemplary embodiment. The table of FIG. 14 shows the relationship between the state of the relay switch 71s of each of the relay RL1 to RL4 and the inductance of the inductor 65. The inductance L of the inductor 65 is L0 when the relay switch 71s of each of the relays RL1 to RL4 is in an open state. When the relay switch 71s of each of the relays RL1 to RL4 is in a closed state, it provides a different inductance L. As a result, as shown in the table of FIG. 14, the inductor 65 may change inductance of the inductor 65 in 16 steps with an equal amount of change in inductance by adjusting the state of the relay switch 71s of each of the relays RL1 to RL4.

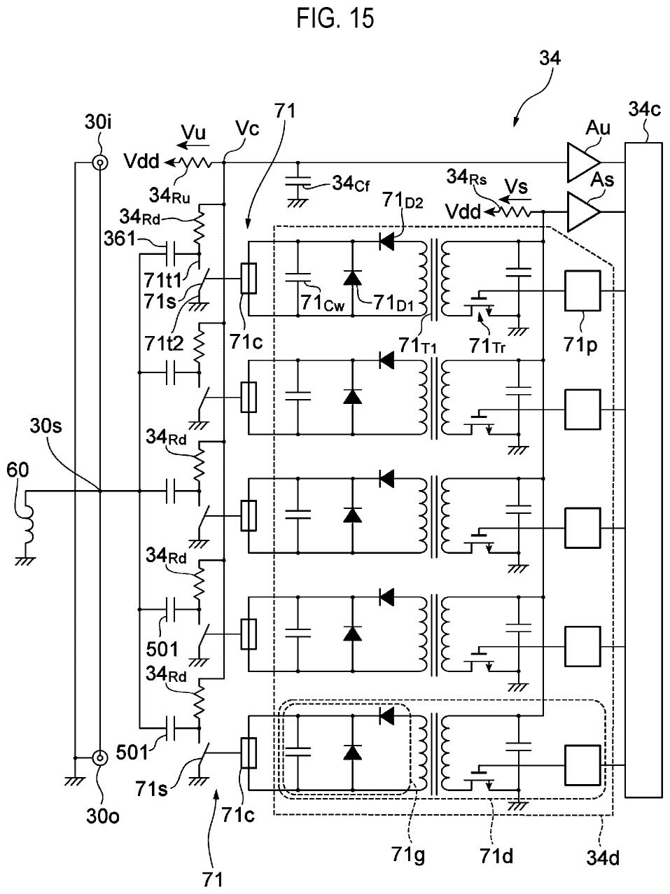

Hereinafter, a configuration for detecting a breakdown of a plurality of relays that is capable of being employed in the coupler according to various exemplary embodiments will be described with reference to FIG. 15. FIG. 15 is a diagram illustrating an example of the configuration for detecting a breakdown of a plurality of relays that is capable of being employed in a coupler according to various exemplary embodiments.

As shown in FIG. 15, in various exemplary embodiments, the variable reactance portion 36 includes a plurality of reactance elements 361. The plurality of reactance elements 361 is the plurality of capacitor elements and/or the plurality of inductor elements described above. The configuration for detecting a breakdown shown in FIG. 15 is applied to the plurality of relays 71 for switching disconnection and connection between the plurality of reactance elements 361 and a ground. In addition, in the example of FIG. 15, a plurality of capacitor elements 501 is shown as the plurality of reactance elements 361. In other embodiments, the configuration of the breakdown detection of the plurality of relays 71 may be similarly applied to a plurality of inductor elements.

As shown in FIG. 15, one end of each of the plurality of reactance elements 361 (e.g., the plurality of capacitor elements 501) is connected to the connection point 30s. The other end of each of the plurality of reactance elements 361 is connected to a first connection point 71t1 of the relay switch 71s of a corresponding relay among the plurality of relays 71. A second connection point 71t2 of the relay switch 71s of each of the plurality of relays 71 is connected to the ground.

As shown in FIG. 15, the matching circuit 34 includes the driving circuit 34d and the control circuit 34c. The driving circuit 34d is configured to set the state (open or closed state) of the relay switch 71s of each of the plurality of relays 71 under the control of the control circuit 34c. The driving circuit 34d may include a plurality of driving circuits 71d that individually control the state of the relay switch 71s of each of the plurality of relays 71. The plurality of driving circuits 71d may be provided as elements of each of the plurality of relays 71. Each of the plurality of driving circuits 71d is configured to generate a DC voltage signal for closing the relay switch 71s of a corresponding relay among the plurality of relays 71.

As shown in FIG. 15, the relay coils 71c of the plurality of relays 71 may be floating from the ground. In this case, each of the plurality of driving circuits 71d includes a transformer 71_{T1}, a pulse generator 71p, and a DC voltage generation circuit 71g. A transistor 71_{Tr} is connected between a primary coil of the transformer 71_{T1} and the ground. The pulse generator 71p generates a radio-frequency pulse and supplies a radio-frequency pulse to a control terminal of the transistor 71_{Tr}. The frequency of the radio-frequency pulse is, for example, 160 kHz. When the radio-frequency pulse is applied to the transistor 71_{Tr}, pulse current is generated in a secondary coil of the transformer 71_{T1}.

The DC voltage generation circuit 71g is connected between the corresponding relay coil 71c and the secondary coil of the transformer 71_{T1}. The DC voltage generation circuit 71g includes a capacitor 71_{Cw}, a first diode 71_{D1}, and a second diode 71_{D2}. One end of the secondary coil is connected to one end of the corresponding relay coil 71c via the second diode 71_{D2}. An anode of the second diode 71_{D2} is connected to one end of the secondary coil, and a cathode of the second diode 71_{D2} is connected to one end of the corresponding relay coil 71c.

A capacitor 71_{Cw} and a first diode 71_{D1} are connected in parallel between the corresponding relay coil 71c and the secondary coil of the transformer 711. A cathode of the first diode 71_{D1} is connected to one end of the corresponding relay coil 71c and the cathode of the second diode 71_{D2}. An anode of the first diode 71_{D1} is connected to the other end of the corresponding relay coil 71c and the other end of the secondary coil.

A pulse current generated in the secondary coil charges the capacitor 71_{Cw} via the second diode 71_{D2}. In addition, when the radio-frequency pulse is in an OFF state, a freewheeling current generated by an inductance component of the relay coil 71c flows through the first diode 71_{D1}. Thereby, a DC voltage is generated in the capacitor 71_{Cw}, and a DC voltage signal is applied to the relay coil 71c. As a result, the relay switch 71s is set to a closed state.

As shown in FIG. 15, the matching circuit 34 includes a common resistor 34_{Ru} (shunt resistor) and a plurality of resistors 34_{Rd}. One end of the common resistor 34_{Ru} is connected to a DC power supply that outputs a voltage Vdd. Each of the plurality of resistors 34_{Rd} is connected between the first connection point 71t1 of the plurality of relays 71 and the other end of the common resistor 34_{Ru}. The other end of the common resistor 34_{Ru} is connected to an A/D conversion terminal of the control circuit 34c via an amplifier Au. A capacitor 34_{Cf} for bypassing radio-frequency current is connected between a ground and an electrical path between the other end of the common resistor 34_{Ru} and the amplifier Au.

A voltage Vu represented by Formula (F3) below is generated at both ends of the common resistor 34_{Ru}.

$$Vu = ( R u / ( R u + R d / N ) ) \times V d d \qquad ( F 3 )$$

Here, Ru is a resistance value of the common resistor 34_{Ru}, Rd is a resistance value of each of the plurality of resistors 34_{Rd}, and N is the number of relays 71 in a closed state.

As indicated by Formula (F3), the voltage Vu increases as the number of relays 71 in the closed state increases. The voltage Vu is input to the A/D conversion terminal of the control circuit 34c via the amplifier Au. The control circuit 34c generates a digital value obtained by A/D conversion for a voltage input to the A/D conversion terminal. The control circuit 34c stores in advance an ideal value of the digital value according to the number of relays 71 in the closed state. The control circuit 34c detects a breakdown of any one of the plurality of relays 71 by comparing the digital value obtained by A/D conversion for the voltage input to the A/D conversion terminal with the ideal value according to the number of relays 71 in the closed state at that time. For example, the control circuit 34c detects that a breakdown has occurred in any one of the plurality of relays 71 when the difference between the digital value obtained by the A/D conversion and the ideal value according to the number of relays 71 in the closed state at that time is greater than a threshold. In this way, the control circuit 34c may function as a detector configured to detect a breakdown in the plurality of relays 71.

In addition, the matching circuit 34 may further include a common resistor 34_{Rs} (shunt resistor). One end of the common resistor 34_{Rs} is connected to a DC power supply that outputs the voltage Vdd, and the other end of the common resistor 34_{Rs} is connected to one end of the primary coil of the transformer 71_{T1}. The other end of the common resistor 34_{Rs} is connected to another A/D conversion terminal of the control circuit 34c via an amplifier As. The DC power supply outputs the voltage Vdd with respect to the common resistor 34_{Rs}. A voltage Vs generated across two terminals of the common resistor 34_{Rs} varies depending on the number of driving circuits 71d that are broken-down on the primary side of the transformer 71_{T1}. Therefore, the control circuit 34c may detect a breakdown in any one of the plurality of driving circuits 71d by comparing the digital value obtained by A/D conversion for the voltage input to another A/D conversion terminal with a prestored value.

While various exemplary embodiment have been described hereinabove, the present disclosure is not limited to the above-described exemplary embodiments, and various additions, omissions, substitutions, and modifications may be made. In addition, elements in different embodiments can be combined to form other embodiments.

Here, various exemplary embodiments included in the present disclosure are described in [E1] to [E17] below.

### [E1]

A plasma processing apparatus includes:
a chamber;
a radio-frequency power supply configured to generate a radio-frequency power and be capable of changing a frequency of the radio-frequency power;
an introducer disposed to introduce electromagnetic waves into a plasma generation region within the chamber;
a resonator having a power feeder, which is an entrance of the electromagnetic waves, and including a waveguide path configured to propagate the electromagnetic waves to the introducer;
a coupler including an input portion to which the radio-frequency power is input, having a variable impedance, and connected between the radio-frequency power supply and the resonator;
   and
a transmission line which is a distributed constant line extending from the input portion to the power feeder via the coupler and has a constant characteristic impedance.

### [E2]

In the plasma processing apparatus of E1, the characteristic impedance is 50Ω.

### [E3]

In the plasma processing apparatus of E1 or E2,
the coupler includes a connection point provided on the transmission line, and a variable reactance portion including a capacitor and/or an inductor and connected between the connection point and a ground, and
a position of the connection point is set so that a change in a reflection coefficient corresponding to an impedance of a load side viewed from the connection point when a reactance of the variable reactance portion is changed and a change in the reflection coefficient when the frequency of the radio-frequency power is changed are orthogonally determined in a coordinate system with a real axis and an imaginary axis orthogonal to each other.

### [E4]

In the plasma processing apparatus of E3,
the resonator includes an inner peripheral portion extending around a central axis of the chamber and the resonator, an outer peripheral portion extending around the central axis, and the waveguide path having a layered structure that alternately folds between the inner peripheral portion and the outer peripheral portion,
the waveguide path includes an upper portion constituting an uppermost layer of the layered structure and having an upper end in the outer peripheral portion, and a lower portion constituting a lowermost layer of the layered structure and having a lower end coupled to the introducer and the waveguide path is configured to resonate the electromagnetic waves propagating through the waveguide path between the upper end and the lower end,
the power feeder is disposed inward of the upper end and in the upper portion, and
the position of the connection point satisfies Equation (1) below:

$$\begin{matrix}[ Equation 1 ] & \\ \frac{{L}_{e}}{{λ}_{ge}} + \frac{{L}_{r}}{{λ}_{g r}} \tilde{=} \frac{2 n + 1}{8} & ( 1 )\end{matrix}$$

where Lᵣ is a length in a radial direction between the power feeder and the upper end, Lₑ is an electric field between the power feeder and the connection point, 2 gr is a wavelength of the electromagnetic waves in the waveguide path of the resonator between the power feeder and the upper end, λ_{ge} is a wavelength of the electromagnetic waves between the power feeder and the connection point, and n is 0 or a positive integer.

### [E5]

In the plasma processing apparatus of E4, the power feeder is provided at a position in the radial direction at which an impedance of a load side from the power feeder becomes 50Ω.

### [E6]

In the plasma processing apparatus of E4, the power feeder is provided at an outer position with respect to a position in the radial direction at which an impedance of a load side from the power feeder becomes 50Ω.

### [E7]

In the plasma processing apparatus of E4, the power feeder is provided at an inner position with respect to a position in the radial direction at which an impedance of a load side from the power feeder becomes 50Ω.

### [E8]

In the plasma processing apparatus of any one of E3 to E6, the capacitor of the variable reactance portion is a variable capacitor.

### [E9]

In the plasma processing apparatus of any one of E3 to E6, wherein the capacitor has a variable capacitance and includes:
a plurality of capacitor elements connected in parallel to the connection point; and
a plurality of relays each including a relay switch connected between a corresponding capacitor element among the plurality of capacitor elements and the ground.

### [E10]

In the plasma processing apparatus of E9, an electrostatic capacity of each of the plurality of capacitor elements satisfies Cₘ=0.5×Cₘ₋₁, where Cₘ is an electrostatic capacity of an m-th capacitor element among first to M-th capacitor elements, which are the plurality of capacitor elements.

### [E11]

In the plasma processing apparatus of E10, wherein the plurality of capacitor elements includes:
a plurality of first electrodes respectively having different areas; and
a second electrode which is common to the plurality of capacitor elements and is configured to face the plurality of first electrodes.

### [E12]

In the plasma processing apparatus of any one of E3 to E5 and E7, the inductor includes a conductor pattern, which extends from one end of the conductor pattern connected to the connection point and short-circuited to the ground, and the inductor is configured so that a length of the conductor pattern from the one end of the conductor pattern to a part short-circuited to the ground is changeable.

### [E13]

In the plasma processing apparatus of E12,
the inductor includes an inductor pattern which is the conductor pattern, and a short-circuit member configured to short-circuit the inductor pattern to the ground, and
the inductor is configured so that a length of the inductor pattern between the connection point and a point at which the short-circuit member contacts the inductor pattern is configured to be changeable.

### [E14]

In the plasma processing apparatus of any one of E3 to E5 and E7,
the inductor includes a conductor plate, and
the conductor plate is connected to the connection point via a connection member extending from the connection point to the conductor plate and configured to be capable of changing a position of the conductor plate so that an electric field between the connection point and the conductor plate is changeable.

### [E15]

In the plasma processing apparatus of any one of E3 to E5 and E7, the inductor includes:
a magnetic core;
a coil wound around the magnetic core; and
a variable current source connected to the coil.

### [E16]

In the plasma processing apparatus of any one of E3 to E5 and E7,
the inductor includes a conductor pattern, and a plurality of relays each including a relay switch connected in parallel between the conductor pattern and the ground, and
the relay switches of the plurality of relays are connected to the conductor pattern at positions at which an electric field from the connection point is different so that an inductance of the inductor is capable of being changed in multiple stages with a same change amount of inductance.

### [E17]

In the plasma processing apparatus of any one of E9 to E11 and E16,
each relay switch of the plurality of relays includes a first connection point and a second connection point connected to the ground, and
the plasma processing apparatus further includes a common resistor connected to a direct current (DC) power supply, a plurality of resistors each connected between the common resistor and the respective first connection point, and a detector configured to detect a breakdown of the plurality of relays based on a voltage at the common resistor.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, and the scope and spirit of the present disclosure are described in the claims.

According to one exemplary embodiment, in a coupler having a variable impedance and connected between a radio-frequency power supply and a resonator, it is possible to suppress a maximum voltage within the coupler caused by transmitted radio-frequency power.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a chamber;
a radio-frequency power supply configured to generate radio-frequency power and be capable of changing a frequency of the radio-frequency power;
an introducer disposed to introduce electromagnetic waves into a plasma generation region within the chamber;
a resonator having a power feeder, which is an entrance of the electromagnetic waves, and including a waveguide path configured to propagate the electromagnetic waves to the introducer;
a coupler including an input portion to which the radio-frequency power is input, having a variable impedance, and connected between the radio-frequency power supply and the resonator;
and
a transmission line which is a distributed constant line extending from the input portion to the power feeder via the coupler and has a constant characteristic impedance.

2. The plasma processing apparatus of claim 1, wherein the characteristic impedance is 50Ω.

3. The plasma processing apparatus of claim 1,
wherein the coupler includes:
a connection point provided on the transmission line; and
a variable reactance portion including at least one of a capacitor or an inductor and connected between the connection point and a ground, and
wherein a position of the connection point is set so that a change in a reflection coefficient corresponding to an impedance of a load side viewed from the connection point when a reactance of the variable reactance portion is changed and a change in the reflection coefficient when the frequency of the radio-frequency power is changed are orthogonal to each other in a coordinate system with a real axis and an imaginary axis orthogonal to each other.

4. The plasma processing apparatus of claim 3,
wherein the resonator includes:
an inner peripheral portion extending around a central axis of the chamber and the resonator;
an outer peripheral portion extending around the central axis; and
the waveguide path having a layered structure that alternately folds between the inner peripheral portion and the outer peripheral portion,
wherein the waveguide path includes:
an upper portion constituting an uppermost layer of the layered structure and having an upper end in the outer peripheral portion; and
a lower portion constituting a lowermost layer of the layered structure and having a lower end coupled to the introducer,
wherein the waveguide path is configured to resonate the electromagnetic waves propagating through the waveguide path between the upper end and the lower end,
wherein the power feeder is disposed inward of the upper end and in the upper portion, and
wherein the position of the connection point satisfies Equation (1) below:
$$\begin{matrix}[ Equation 1 ] & \\ \frac{{L}_{e}}{{λ}_{ge}} + \frac{{L}_{r}}{{λ}_{g r}} \tilde{=} \frac{2 n + 1}{8} & ( 1 )\end{matrix}$$
where Lᵣ is a length in a radial direction between the power feeder and the upper end, Lₑ is an electric field between the power feeder and the connection point, λ_{gr} is a wavelength of the electromagnetic waves in the waveguide path of the resonator between the power feeder and the upper end, λ_{ge} is a wavelength of the electromagnetic waves between the power feeder and the connection point, and n is 0 or a positive integer.

5. The plasma processing apparatus of claim 4, wherein the power feeder is provided at a position in the radial direction at which an impedance of a load side from the power feeder becomes 50Ω.

6. The plasma processing apparatus of claim 4, wherein the power feeder is provided at an outer position with respect to a position in the radial direction at which an impedance of a load side from the power feeder becomes 50Ω.

7. The plasma processing apparatus of claim 4, wherein the power feeder is provided at an inner position with respect to a position in the radial direction at which an impedance of a load side from the power feeder becomes 50Ω.

8. The plasma processing apparatus of claim 3, wherein the capacitor of the variable reactance portion is a variable capacitor.

9. The plasma processing apparatus of claim 3, wherein the capacitor has a variable capacitance and includes:
a plurality of capacitor elements connected in parallel to the connection point; and
a plurality of relays each including a relay switch connected between a corresponding capacitor element among the plurality of capacitor elements and the ground.

10. The plasma processing apparatus of claim 9, wherein an electrostatic capacity of each of the plurality of capacitor elements satisfies Cₘ=0.5×Cₘ₋₁, where Cₘ is an electrostatic capacity of an m-th capacitor element among first to M-th capacitor elements, which are the plurality of capacitor elements.

11. The plasma processing apparatus of claim 10, wherein the plurality of capacitor elements includes:
a plurality of first electrodes respectively having different areas; and
a second electrode which is common to the plurality of capacitor elements and is configured to face the plurality of first electrodes via a dielectric member.

12. The plasma processing apparatus of claim 9,
wherein each relay switch of the plurality of relays includes a first connection point and a second connection point connected to the ground, and
wherein the plasma processing apparatus further comprises:
a common resistor connected to a direct current (DC) power supply;
a plurality of resistors each connected between the common resistor and the respective first connection point; and
a detector configured to detect a breakdown of the plurality of relays based on a voltage at the common resistor.

13. The plasma processing apparatus of claim 3, wherein the inductor includes a conductor pattern, which extends from one end of the conductor pattern connected to the connection point and short-circuited to the ground, and
wherein the inductor is configured so that a length of the conductor pattern from the one end of the conductor pattern to a part short-circuited to the ground is changeable.

14. The plasma processing apparatus of claim 13,
wherein the inductor includes:
an inductor pattern which is the conductor pattern; and
a short-circuit member configured to short-circuit the inductor pattern to the ground, and
wherein the inductor is configured so that a length of the inductor pattern between the connection point and a point at which the short-circuit member contacts the inductor pattern is changeable.

15. The plasma processing apparatus of claim 3,
wherein the inductor includes a conductor plate, and
wherein the conductor plate is connected to the connection point via a connection member extending from the connection point to the conductor plate and configured to be capable of changing a position of the conductor plate so that an electric field between the connection point and the conductor plate is changeable.

16. The plasma processing apparatus of claim 3, wherein the inductor includes:
a magnetic core;
a coil wound around the magnetic core; and
a variable current source connected to the coil.

17. The plasma processing apparatus of claim 3,
wherein the inductor includes:
a conductor pattern; and
a plurality of relays each including a relay switch connected in parallel between the conductor pattern and the ground, and
wherein the relay switches of the plurality of relays are connected to the conductor pattern at positions at which an electric field from the connection point is different so that an inductance of the inductor is capable of being changed in multiple stages with an equal amount of change in inductance.

18. The plasma processing apparatus of claim 17,
wherein each relay switch of the plurality of relays includes a first connection point and a second connection point connected to the ground, and
wherein the plasma processing apparatus further comprises:
a common resistor connected to a direct current (DC) power supply;
a plurality of resistors each connected between the common resistor and the respective first connection point; and
a detector configured to detect a breakdown of the plurality of relays based on a voltage at the common resistor.
